(19) United States
(12) Patent Application Publication
(10) Pub. No.: US 2004/0137757 A1
(43) Pub. Date: Jul. 15, 2004

(54) Method and apparatus to improve cracking thresholds and mechanical properties of low-k dielectric material

(75) Inventors: Lihua Li, San Jose, CA (US); Tzu-Fang Huang, San Jose, CA (US); Juan C. Rocha-Alvarez, Sunnyvale, CA (US); Li-Qun Xia, Santa Clara, CA (US)

Correspondence Address: PATENT COUNSEL, MS/2061, APPLIED MATERIALS, INC., Legal Affairs Department, P.O.BOX 450A, Santa Clara, CA, 95052, US

(73) Assignee: Applied Materials, Inc.

(21) Appl. No.: 10/342,085

(22) Filed: Jan. 13, 2003

(51) Int. Cl. H01L 21/31; H01L 21/469

(52) U.S. Cl. 438/778; 438/780

(57) ABSTRACT

One embodiment of the present invention is a method for depositing low-k dielectric films that includes steps of: (a) CVD-depositing a low-k dielectric film; and (b) plasma treating the CVD-deposited, low-k dielectric film.

### TECHNICAL FIELD OF THE INVENTION

One or more embodiments of the present invention pertain to method and apparatus to improve one or more properties of low dielectric constant (“low-k”) materials used to fabricate integrated circuit (“IC”) devices.

### BACKGROUND OF THE INVENTION

Fabrication of integrated devices (“ICs”), for example, and without limitation, semiconductor ICs, is complicated and, due to increasingly stringent requirements on device designs due to demands for greater device speed, fabrication is becoming ever more complicated. Today's fabrication facilities are routinely producing devices having 0.13 μm feature sizes, and tomorrow's facilities soon will be producing devices having even smaller feature sizes. In addition, ICs are being layered or stacked with ever decreasing insulating thickness between each layer of circuitry.

In the production of advanced ICs that have minimum feature sizes of 0.13 μm and below, problems of RC delay, power consumption, and crosstalk become significant. For example, device speed is limited in part by the RC delay which is determined by the resistance of the metal used in the interconnect scheme, and the dielectric constant of the insulating dielectric material used between the metal interconnects. In addition, with decreasing geometries and device sizes, the semiconductor industry has sought to avoid parasitic capacitance and crosstalk noise caused by inadequate insulating layers in the integrated circuits. One way to achieve the desired low RC delay and higher performance in ICs in devices involves the use of dielectric materials in the insulating layers that have a low dielectric constant (“low-k” materials).

Process steps to reduce the dielectric constant of a material must also improve one or more of its cracking threshold and its mechanical properties.

### SUMMARY OF THE INVENTION

One or more embodiments of the present invention advantageously satisfy one or more of the above-identified needs in the art. In particular, one embodiment of the present invention is a method for depositing low-k dielectric films that comprises steps of: (a) CVD-depositing a low-k dielectric film; and (b) plasma treating the CVD-deposited, low-k dielectric film.

### BRIEF DESCRIPTION OF THE FIGURE

FIG. 1 is a cross-sectional diagram of an exemplary CVD reactor configured for use according to embodiments described herein.

### DETAILED DESCRIPTION

In accordance with one or more embodiments of the present invention, the cracking threshold and mechanical properties of a CVD-deposited, low-k dielectric film are improved by plasma treatment. It is believed that, at least in one respect, such improvement is provided because the plasma treatment acts to create more Si—H bonds, thereby densifying and increasing the bulk hardness and the Young's modulus of the film.

In accordance with one or more embodiments of the present invention, in a first step of a method of producing a low-k dielectric film having improved cracking threshold and mechanical properties, a low-k dielectric film is deposited using a CVD deposition process (in the manner that is described in detail below). Next, in accordance with such one or more embodiments of the present invention, in a second step of the method of producing a low-k dielectric film having improved cracking threshold and mechanical properties, a plasma treatment (including optionally heating the film at the same time) is carried out on the CVD-deposited film.

One or more embodiments of the first step of depositing a low-k dielectric film entails depositing a low-k dielectric film containing silicon, oxygen, and carbon. In accordance with one or more such embodiments, the deposition entails the use of a precursor comprised of one or more cyclic organo-silicon-based compounds. Further, such embodiments entail blending one or more cyclic organo-silicon-based compounds and one or more acyclic organo-silicon compounds. In one aspect of such an embodiment, a cyclic organo-silicon compound, an acyclic organo-silicon, and a hydrocarbon compound are reacted with an oxidizing gas at conditions sufficient to form a low-k dielectric film having k less than or equal to about 2.5. The cyclic organo-silicon compound includes at least one silicon-carbon bond. The acyclic organo-silicon compound includes, for example, and without limitation, a silicon-hydrogen bond or a silicon-oxygen bond. The hydrocarbon could be linear or cyclic, and may include a carbon-carbon double or triple bond. In accordance with one or more embodiments of the present invention, if at least one the organo-silicon gases contains oxygen, one may not need an oxidizing gas.

Such CVD-deposited low-k films contain a network of —Si—O—Si— ring structures that are cross-linked with one or more linear organic compounds. Because of the cross-linkage, a reactively stable network is produced having a greater separation between ring structures, and thus, the deposited films possess a greater degree of porosity than prior art CVD-deposited films.

Such CVD-deposited low-k films also comprise a carbon content between about 10 and about 30 atomic percent (excluding hydrogen atoms), and preferably between about 10 and about 20 atomic percent. The carbon content of such CVD-deposited low-k films refers to an atomic analysis of the film structure which typically does not contain significant amounts of non-bonded hydrocarbons. The carbon contents are represented by the percent of carbon atoms in the deposited film, excluding hydrogen atoms which are difficult to quantify. For example, a film having an average of one silicon atom, one oxygen atom, one carbon atom and two hydrogen atoms has a carbon content of 20 atomic percent (one carbon atom per five total atoms), or a carbon content of 33 atomic percent excluding hydrogen atoms (one carbon atom per three total atoms).

The cyclic organo-silicon compounds may include a ring structure having three or more silicon atoms, and the ring structure may further comprise one or more oxygen atoms. Commercially available cyclic organo-silicon compounds include rings having alternating silicon and oxygen atoms with one or two alkyl groups bonded to the silicon atoms. For example, the cyclic organo-silicon compounds may include one or more of the following compounds:

| | |
|---|---|
| 1,3,5-trisilano-2,4,6-trimethylene | —(—SiH₂CH₂—)₃-(cyclic) |
| 1,3,5,7-tetramethylcyclotetrasiloxane | —(—SiHCH₃—O—)₄-(cyclic) |
| (TMCTS) | |
| octamethylcyclotetrasiloxane | —(—Si(CH₃)₂—O—)₄-(cyclic) |
| (OMCTS) | |
| 1,3,5,7,9- | —(—SiHCH₃—O—)₅-(cyclic) |
| pentamethylcyclopentasiloxane | |
| 1,3,5,7-tetrasilano-2,6-dioxy- | —(—SiH₂—CH₂—SiH₂—O—)₂- |
| 4,8-dimethylene | (cyclic) |
| hexamethylcyclotrisiloxane | —(—Si(CH₃)₂—O—)₃-(cyclic) |

The acyclic organo-silicon compounds include linear or branched (i.e. acyclic) organo-silicon compounds having one or more silicon atoms and one or more carbon atoms and linear or branched hydrocarbon compounds having at least one unsaturated carbon bond. The structures may further contain oxygen. Commercially available acyclic organo-silicon compounds include organo-silanes that do not contain oxygen between silicon atoms and organo-siloxanes which contain oxygen between two or more silicon atoms. For example, the acyclic organo-silicon compounds may include one or more of the following compounds:

| | |
|---|---|
| methylsilane | CH₃—SiH₃ |
| dimethylsilane | (CH₃)₂—SiH₂ |
| trimethylsilane | (CH₃)₃—SiH |
| tetramethylsilane | (CH₃)₄—Si |
| dimethyldimethoxysilane | (CH₃)₂—Si—(OCH₃)₂ |
| (DMDMOS) | |
| ethylsilane | CH₃—CH₂—SiH₃ |
| disilanomethane | SiH₃—CH₂—SiH₃ |
| bis(methylsilano)methane | CH₃—SiH₂—CH₂—SiH₂—CH₃ |
| 1,2-disilanoethane | SiH₃—CH₂—CH₂—SiH₃ |
| 1,2-bis(methylsilano)ethane | CH₃—SiH₂—CH₂—CH₂—SiH₂—CH₃ |
| 2,2-disilanopropane | SiH₃—C(CH₃)₂—SiH₃ |
| 1,3-dimethyldisiloxane | CH₃—SiH₂—O—SiH₂—CH₃ |
| 1,1,3,3-tetramethyldisiloxane | (CH₃)₂—SiH—O—SiH—(CH₃)₂ |
| (TMDSO) | |
| hexamethyldisiloxane (HMDS) | (CH₃)₃—Si—O—Si—(CH₃)₃ |
| 1,3- | (SiH₃—CH₂—SiH₂—)₂—O |
| bis(silanomethylene)disiloxane | |
| bis(1- | (CH₃—SiH₂—O—SiH₂—)₂—CH₂ |
| methyldisiloxanyl)methane | |
| 2,2-bis(1- | (CH₃—SiH₂—O—SiH₂—)₂—C(CH₃)₂ |
| methyldisiloxanyl)propane | |
| hexamethoxydisiloxane | (CH₃O)₃—Si—O—Si—(OCH₃)₃ |
| (HMDOS) | |
| diethylsilane | ((C₂H₅)₂SiH₂) |
| propylsilane | (C₃H₇SiH₃) |
| vinylmethylsilane | (CH₂═CH)CH₃SiH₂) |
| 1,1,2,2-tetramethyldisilane | (HSi(CH₃)₂—Si(CH₃)₂H) |
| hexamethyldisilane | ((CH₃)₃Si—Si(CH₃)₃) |
| 1,1,2,2,3,3-hexamethyltrisilane | (H(CH₃)₂Si—Si(CH₃)₂—SiH(CH₃)₂) |
| 1,1,2,3,3-pentamethyltrisilane | (H(CH₃)₂Si—SiH(CH₃)—SiH(CH₃)₂) |
| dimethyldisilanoethane | (CH₃—SiH₂—(CH₂)₂—SiH₂—CH₃) |
| dimethyldisilanopropane | (CH₃—SiH—(CH₂)₃—SiH—CH₃) |
| tetramethyldisilanoethane | ((CH)₂—SiH—(CH₂)₂—SiH—(CH)₂) |
| tetramethyldisilanopropane | ((CH₃)₂—Si—(CH₂)₃—Si—(CH₃)₂) |

The linear or branched hydrocarbon compounds include between one and about 20 adjacent carbon atoms. The hydrocarbon compounds can include adjacent carbon atoms that are bonded by any combination of single, double, and triple bonds. For example, the organic compounds may include alkenes having two to about 20 carbon atoms, such as ethylene, propylene, acetylene, butadiene, t-butylethylene, 1,1,3,3-tetramethylbutylbenzene, t-butylether, methyl-methacrylate (MMA), and t-butylfurfurylether.

Some of the above-described precursors contain oxygen, therefore an additional oxidizer may not be needed. However, in case one or more oxidizing gases or liquids are needed, they may include oxygen (O₂), ozone (O₃), nitrous oxide (N₂O), carbon monoxide (CO), carbon dioxide (CO₂), water (H₂O), hydrogen peroxide (H₂O₂), an oxygen-containing organic compound, or combinations thereof. Preferably, the oxidizing gas is oxygen gas. However, when ozone is used as an oxidizing gas, an ozone generator converts from 6% to 20%, typically about 15%, by weight of the oxygen in a source gas to ozone, with the remainder typically being oxygen. Yet, the ozone concentration may be increased or decreased based upon the amount of ozone desired and the type of ozone generating equipment used. The one or more oxidizing gases are added to the reactive gas mixture to increase reactivity and achieve the desired carbon content in the deposited film.

Deposition of the low-k dielectric film can be continuous or discontinuous in a single deposition chamber. Alternatively, the film can be deposited sequentially in two or more deposition chambers, such as within a cluster tool like the Producer™ available from Applied Materials, Inc. of Santa Clara, Calif.

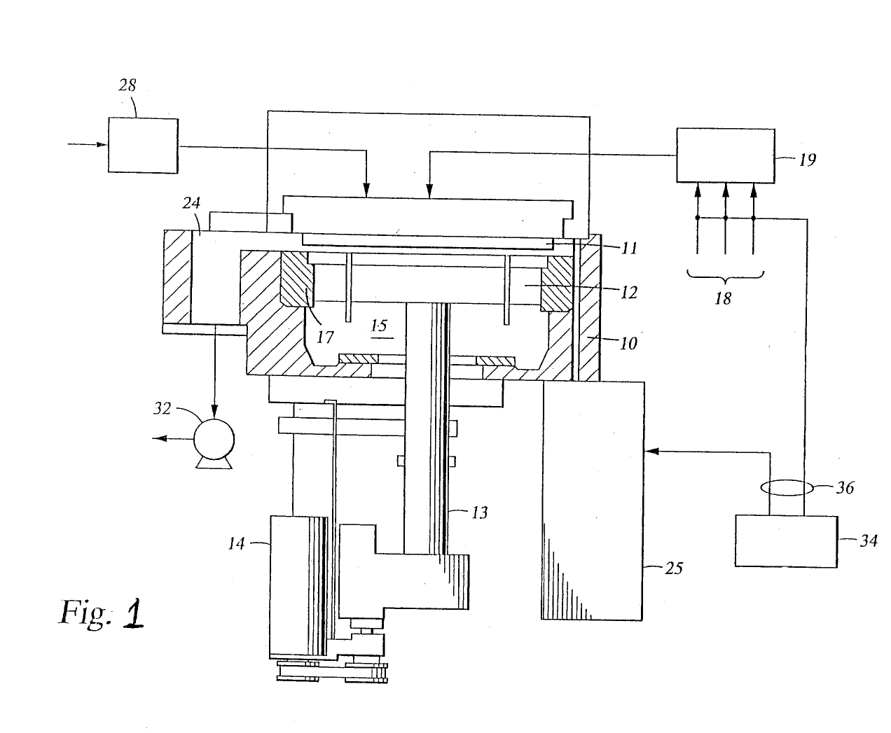

FIG. 1 shows a vertical, cross-section view of parallel plate chemical vapor deposition (CVD) processing chamber 10 having a high vacuum region 15. Processing chamber 10 contains gas distribution manifold 11 having perforated holes for dispersing process gases there-through to a substrate (not shown). The substrate rests on substrate support plate or susceptor 12. Susceptor 12 is mounted on support stem 13 that connects susceptor 12 to lift motor 14. Lift motor 14 raises and lowers susceptor 12 between a processing position and a lower, substrate-loading position so that susceptor 12 (and the substrate supported on the upper surface of susceptor 12) can be controllably moved between a lower loading/off-loading position and an upper processing position which is closely adjacent to manifold 11. Insulator 17 surrounds susceptor 12 and the substrate when in an upper processing position.

During processing, gases introduced to manifold 11 are uniformly distributed radially across the surface of the substrate by a showerhead. Vacuum pump 32 having a throttle valve controls the exhaust rate of gases from chamber 10 through manifold 24. Deposition and carrier gases flow through gas lines 18 into mixing system 19 and then to manifold 11. Generally, each process gas supply line 18 includes (i) safety shut-off valves (not shown) that can be used to automatically or manually shut off the flow of process gas into the chamber, and (ii) mass flow controllers (also not shown) to measure the flow of gas through gas supply lines 18. When toxic gases are used in the process, several safety shut-off valves are positioned on each gas supply line 18 in conventional configurations.

During deposition, a blend/mixture of one or more cyclic organo-silicon compounds and one or more acyclic organo-silicon compounds are reacted with an oxidizing gas to form a low-k dielectric film on the substrate. In accordance with one such embodiment, the cyclic organo-silicon compounds are combined with at least one acyclic organo-silicon compound and at least one hydrocarbon compound. For example, the mixture contains about 5 percent by volume to about 80 percent by volume of the one or more cyclic organo-silicon compounds, about 5 percent by volume to about 15 percent by volume of the one or more acyclic organo-silicon compounds, and about 5 percent by volume to about 45 percent by volume of the one or more hydrocarbon compounds. The mixture also contains about 5 percent by volume to about 20 percent by volume of one or more oxidizing gases. In accordance with one such embodiment, the mixture contains about 45 percent by volume to about 60 percent by volume of one or more cyclic organo-silicon compounds, about 5 percent by volume to about 10 percent by volume of one or more acyclic organo-silicon compounds, and about 5 percent by volume to about 35 percent by volume of one or more hydrocarbon compounds.

In one aspect, the one or more cyclic organo-silicon compounds are introduced to mixing system 19 at a flow rate of about 1,000 to about 10,000 mgm, and in accordance with one embodiment, about 5,000 mgm. The one or more acyclic organo-silicon compounds are introduced to mixing system 19 at a flow rate of about 200 to about 2,000, and in accordance with one embodiment, about 700 sccm. The one or more hydrocarbon compounds are introduced to the mixing system 19 at a flow rate of about 100 to about 10,000 sccm, and in accordance with one embodiment, 1,000 sccm. The oxygen containing gas has a flow rate between about 200 and about 5,000 sccm. In accordance with one embodiment, the cyclic organo-silicon compound is 2,4,6,8-tetramethylcyclotetrasiloxane, octamethylcyclotetrasiloxane, or a mixture thereof, and the acyclic organo-silicon compound is trimethylsilane, 1,1,3,3-tetramethyldisiloxane, or a mixture thereof. In accordance with one embodiment, the hydrocarbon compound is ethylene.

The deposition process can be either a thermal process or a plasma enhanced process. In a plasma enhanced process, a controlled plasma is typically formed adjacent the substrate by RF energy applied to gas distribution manifold 11 using RF power supply 25. Alternatively, RF power can be provided to susceptor 12. The RF power to the deposition chamber may be cycled or pulsed to reduce heating of the substrate and promote greater porosity in the deposited film. The power density of the plasma for a 200 mm substrate is between about 0.03 W/cm² and about 3.2 W/cm², which corresponds to a RF power level of about 10 W to about 2000 W. In accordance with one embodiment, the RF power level is between about 300 W and about 1700 W.

RF power supply 25 can supply a single frequency RF power between about 0.01 MHz and 300 MHz. Alternatively, the RE power may be delivered using mixed, simultaneous frequencies to enhance the decomposition of reactive species introduced into high vacuum region 15. In one aspect, the mixed frequency is a lower frequency of about 12 kHz and a higher frequency of about 13.56 MHz. In another aspect, the lower frequency may range between about 300 Hz to about 1,000 kHz, and the higher frequency may range between about 5 MHz and about 50 MHz.

During deposition, the substrate is maintained at a temperature between about −20° C. and about 500° C., and in accordance with one embodiment, between about 100° C. and about 400° C. The deposition pressure is typically between about 1 Torr and about 20 Torr, and in accordance with one embodiment, between about 4 Torr and about 6 Torr. The deposition rate is typically between about 10,000 Å/min and about 20,000 Å/min.

When additional dissociation of the oxidizing gas is desired, an optional microwave chamber 28 can be used to input from between about 0 Watts and about 6000 Watts to the oxidizing gas prior to the gas's entering processing chamber 10. The additional microwave power can avoid excessive dissociation of the organo-silicon compounds prior to reaction with the oxidizing gas. A gas distribution plate (not shown) having separate passages for the organo-silicon compound and the oxidizing gas is preferred when microwave power is added to the oxidizing gas.

Typically, any or all of the chamber lining, distribution manifold 11, susceptor 12, and various other reactor hardware is made out of materials such as aluminum or anodized aluminum. An example of such a CVD reactor is described in U.S. Pat. No. 5,000,113, entitled “A Thermal CVD/PECVD Reactor and Use for Thermal Chemical Vapor Deposition of Silicon Dioxide and In-situ Multi-step Planarized Process,” issued to Wang et al. and assigned to Applied Materials, Inc., the assignee of the present invention.

System controller 34 controls motor 14, gas mixing system 19, and RF power supply 25 which are connected therewith by control lines 36. System controller 34 controls the activities of the CVD reactor and typically includes a hard disk drive, a floppy disk drive, and a card rack. The card rack contains a single board computer (SBC), analog and digital input/output boards, interface boards, and stepper motor controller boards. System controller 34 conforms to the Versa Modular Europeans (VME) standard which defines board, card cage, and connector dimensions and types. The VME standard also defines the bus structure having a 16-bit data bus and 24-bit address bus. System controller 34 operates under the control of a computer program that is stored on the hard disk drive. As is well known, the computer program dictates the timing, mixture of gases, RF power levels, susceptor position, and other parameters of a particular process.

Operation of particular chamber components will now be described with reference to FIG. 1. When a substrate is loaded into processing chamber 10, susceptor 12 is lowered to receive the substrate, and thereafter, susceptor 12 is raised to the desired height in the chamber to maintain the substrate at a first distance or spacing from gas distribution manifold 11 during the CVD process. In some processes, an inert gas such as helium or argon is put into processing chamber 10 to stabilize the pressure in the chamber before reactive process gases are introduced.

The above CVD system description is mainly for illustrative purposes, and other CVD equipment such as electrode cyclotron resonance (ECR) plasma CVD devices, induction-coupled RF high density plasma CVD devices, or the like may be employed. Additionally, variations of the above described system such as variations in susceptor design, heater design, location of RF power connections and others are possible. For example, the substrate could be supported and heated by a resistively heated susceptor.

The following example illustrates a typical low-k dielectric film that was deposited using the above-described CVD chamber. In particular, the film was deposited using a “Producer” system, which is available from Applied Materials, Inc. of Santa Clara, Calif.

### EXAMPLE OF THE FIRST STEP OF CVD DEPOSITING A LOW-K DIELECTRIC FILM

A low-k dielectric film was deposited on a 300 mm substrate from the following reactive gases at a chamber pressure of about 5.75 Torr, and a substrate temperature of about 400° C.: a flow rate for octamethylcyclotetrasiloxane (OMCTS) of about 6,400 mgm; a flow rate for trimethylsilane (TMS) of about 575 sccm; a flow rate of ethylene of about 3200 sccm; a flow rate of oxygen of about 1,600 sccm; and a flow rate of Helium of about 1,600 sccm. The substrate was positioned about 1,050 mils from the gas distribution showerhead, and a power level of about 1200 W at a frequency of about 13.56 MHz was applied to the showerhead for plasma enhanced deposition of the film. The film was deposited at a rate of about 13,000 Å/min, and had a dielectric constant (k) of about 2.54 measured at about 0.1 MHz.

After the above-described films are deposited, they are plasma treated (a post-deposition plasma treatment) using, for example, and without limitation, a chamber like that described above in conjunction with FIG. 1. In accordance with one or more embodiments of the present invention, the plasma is formed using one or more of the following gases: H₂, He, Ar, and SiF₄. In addition, the plasma is generated by applying power to the gas distribution manifold at a frequency in a range from about 2 MHz to about 100 MHz at a power in a range from about 10 W to about 1500 W (and preferably in a range from about 200 W to about 600 W) from a first power source, and by applying power to the gas distribution manifold at a frequency in a range from about 100 kHz to about 500 kHz at a power in a range from about 10 W to about 1500 W from a second power source. In accordance with one or more embodiments of the present invention, the wafer pedestal is maintained at a temperature in a range of about 200° C. to about 500° C., and the plasma treatment last for a time in a range from about 5 sec to 50 sec. In accordance with one or more further embodiments of the present invention, the low-k dielectric film is deposited as a multiplicity of layers where a post-deposition plasma treatment step follows each step of deposition. In accordance with one or more still further embodiments of the present invention, the plasma treatment takes place in a chamber other than one utilized to plasma-CVD deposit the low-k dielectric film.

### Example 1 of the Second Step of Plasma Treatment of the CVD-Deposited, Low-k Dielectric Film

The film was plasma treated for about 30 sec utilizing H₂ at a flow rate of about 500 sccm at a chamber pressure of about 5.0 Torr, and a substrate temperature of about 400° C. The substrate was positioned about 1,000 mils from the gas distribution showerhead, and a power level of about 550 W at a frequency of about 13.56 MHz was applied to the showerhead. The resulting film had a hardness of about 1 GPa, and a Young's Modulus of about 5.8 GPa.

### Example 2 of the Second Step of Plasma Treatment of the CVD-Deposited, Low-k Dielectric Film

The film was plasma treated for about 10 sec utilizing H₂ at a flow rate of about 500 sccm at a chamber pressure of about 5.0 Torr, and a substrate temperature of about 400° C. The substrate was positioned about 1,000 mils from the gas distribution showerhead, and a power level of about 650 W at a frequency of about 13.56 MHz was applied to the showerhead. The resulting film had a hardness of about 0.8 GPa, and a Young's Modulus of about 5.2 GPa.

In practice, the above-described post-deposition plasma treatment improved the cracking threshold of a low-k film (for example, one deposited as described above) from an untreated cracking threshold thickness value of about 1.0 μm to a post-deposition treatment cracking threshold thickness value of about 1.2 μm. In addition, the above-described multi-layer post-deposition plasma treatment improved the cracking threshold of a multi-layer-deposited low-k film to a cracking threshold thickness value of over about 2.5 μm. In addition, mechanical properties of the post-treatment films such as, for example, hardness and Young's modulus also improved.

Those skilled in the art will recognize that the foregoing description has been presented for the sake of illustration and description only. As such, it is not intended to be exhaustive or to limit the invention to the precise form disclosed. For example, although certain dimensions were discussed above, they are merely illustrative since various designs may be fabricated using the embodiments described above, and the actual dimensions for such designs will be determined in accordance with circuit requirements. In addition, the term substrates include those suitable to be processed into an integrated circuit or other microelectronic device, and is used in the broadest sense of the word. Suitable substrates for the present invention non-exclusively include semiconductor materials such as gallium arsenide (GaAs), germanium, silicon, silicon germanium, lithium niobate and compositions containing silicon such as crystalline silicon, polysilicon, amorphous silicon, epitaxial silicon, and silicon oxide and combinations mixtures thereof. The term substrates also include glass substrates of any kind.

What is claimed is:

1. A method for depositing low-k dielectric films comprises steps of:
CVD-depositing a low-k dielectric film; and
plasma treating the CVD-deposited, low-k dielectric film.

2. The method of claim 1 wherein the step of CVD-depositing a low-k dielectric film comprises steps of depositing a low-k dielectric film containing silicon, oxygen, and carbon.

3. The method of claim 2 wherein the steps of depositing a low-k dielectric film containing silicon, oxygen, and carbon comprise use of a precursor comprised of one or more cyclic organo-silicon-based compounds.

4. The method of claim 2 wherein the wherein the steps of depositing a low-k dielectric film containing silicon, oxygen, and carbon comprise use of a precursor comprised of one or more cyclic organo-silicon-based compounds and one or more acyclic organo-silicon compounds.

5. The method of claim 2 wherein the steps of depositing a low-k dielectric film containing silicon, oxygen, and carbon comprise use of a precursor comprised of a cyclic organo-silicon compound, an acyclic organo-silicon, a hydrocarbon compound, and an oxidizer.

6. The method of claim 5 wherein the cyclic organo-silicon compound includes at least one silicon-carbon bond.

7. The method of claim 5 wherein the acyclic organo-silicon compound includes a silicon-hydrogen bond or a silicon-oxygen bond.

8. The method of claim 5 wherein the hydrocarbon is linear or cyclic.

9. The method of claim 1 wherein the CVD-deposited low-k film comprises a carbon content between about 10 and about 30 atomic percent excluding hydrogen atoms.

10. The method of claim 5 wherein the oxidizer comprises one or more of oxygen (O₂), ozone (O₃), nitrous oxide (N₂O), carbon monoxide (CO), carbon dioxide (CO₂), water (H₂O), hydrogen peroxide (H₂O₂), an oxygen-containing organic compound, or combinations of any of the foregoing.

11. The method of claim 1 wherein the step of CVD-depositing a low-k dielectric film comprises use of a precursor including one or more cyclic organo-silicon compounds and one or more acyclic organo-silicon compounds.

12. The method of claim 11 wherein the step of CVD-depositing comprises use of a precursor including one or more cyclic organo-silicon compounds, at least one acyclic organo-silicon compound and at least one hydrocarbon compound.

13. The method of claim 12 wherein the precursor comprises about 5 percent by volume to about 80 percent by volume of the one or more cyclic organo-silicon compounds, about 5 percent by volume to about 15 percent by volume of the one or more acyclic organo-silicon compounds, and about 5 percent by volume to about 45 percent by volume of the one or more hydrocarbon compounds.

14. The method of claim 13 wherein the precursor further includes about 5 percent by volume to about 20 percent by volume of one or more oxidizing gases.

15. The method of claim 1 wherein the step of plasma treating comprises forming a plasma utilizing one or more of the following gases: H₂, He, Ar, and SiF₄.

16. The method of claim 15 wherein the plasma treatment is carried out for a time in a range from about 5 sec to about 50 sec.

17. The method of claim 16 wherein the plasma treatment is carried out in a capacitively-coupled plasma chamber where source power is applied at a frequency in a range from about 2 MHz to about 100 MHz to generate and sustain the plasma.

18. The method of claim 17 where a bias power is applied to a wafer holder in the chamber at a frequency in a range from about 100 kHz to about 500 kHz.

19. The method of claim 18 wherein a ratio of the source power to the bias power is in a range from about 0.1:1 to about 15:1.

20. The method of claim 19 wherein the wafer holder is maintained in a range from about 200° C. to about 500° C.

21. The method of claim 1 wherein the step of CVD-depositing a low-k dielectric film comprises use of a precursor comprised of octamethylcyclotetrasiloxane, trimethylsilane, ethylene, and oxygen.

22. The method of claim 1 wherein the step of CVD-depositing a low-k dielectric film comprises a plasma enhanced process.

23. The method of claim 22 wherein the plasma enhanced process includes applying RF power to form a plasma adjacent a substrate upon which the low-k dielectric film is deposited.

24. The method of claim 23 wherein the RF power is cycled.

25. The method of claim 23 wherein the RF power is pulsed.
